(19) United States
(12) Patent Application Publication
(10) Pub. No.: US 2026/0254414 A1
(43) Pub. Date: Aug. 27, 2026

(54) OUTPHASING AMPLIFIER

(71) Applicant: SUMITOMO ELECTRIC INDUSTRIES, LTD., Osaka-shi, Osaka (JP)

(72) Inventor: Takashi SUMIYOSHI, Osaka-shi (JP)

(73) Assignee: SUMITOMO ELECTRIC INDUSTRIES, LTD., Osaka-shi, Osaka (JP)

(21) Appl. No.: 18/872,621

(22) PCT Filed: Aug. 15, 2022
(86) PCT No.: PCT/JP2022/030874

§ 371 Date: Dec. 6, 2024

(30) Foreign Application Priority Data
Jun. 9, 2022 (JP) 2022-093858

(51) Int. Cl. H03F 1/02; H03F 3/68

(52) U.S. Cl. CPC H03F 1/0294; H03F 3/68

(57) ABSTRACT

An outphasing amplifier includes a first amplifier that amplifies a first signal, a second amplifier that amplifies a second signal, a combiner that combines amplified first signal and amplified second signal and outputs a combined signal as an output signal, and a signal processor that sets an amplitude of the second signal to be equal to or greater than an amplitude of the first signal when setting an output power of the output signal to be maximum, sets the amplitude of the second signal to be smaller than the amplitude of the first signal when setting the output power to be minimum, sets an outphasing angle of the first signal and the second signal when setting the output power to be maximum to be larger than the outphasing angle when setting the output power to be minimum, and outputs the first signal and the second signal.

### TECHNICAL FIELD

The present disclosure relates to an outphasing amplifier. This application is based upon and claims the benefit of priority of Japanese Patent Application No. 2022-093858, filed on Jun. 9, 2022, the entire contents of which are incorporated herein by reference.

### BACKGROUND ART

An outphasing amplifier is known as an amplifier for amplifying a high-frequency signal such as a microwave. The outphasing amplifier includes a signal processor, two amplifiers and a combiner. The signal processor outputs two signals in which an outphasing angle is changed based on the amplitude of an input signal. The two amplifiers amplify the two signals output from the signal processor, respectively. The combiner includes a combiner that combines two output signals amplified by two amplifiers as one output signal. It is known to use a Chireix combiner as a combiner (for example, PTL 1).

### CITATION LIST

### Patent Literature

PTL 1: Japanese Laid-open Patent Publication No. 2020-156023

### SUMMARY OF INVENTION

An outphasing amplifier according to an aspect of the present disclosure includes: a first amplifier that amplifies a first signal; a second amplifier that amplifies a second signal; a combiner that combines the first signal amplified by the first amplifier and the second signal amplified by the second amplifier and outputs a combined signal as an output signal; and a signal processor that sets an amplitude of the second signal to be equal to or greater than an amplitude of the first signal when setting an output power of the output signal to be maximum, sets the amplitude of the second signal to be smaller than the amplitude of the first signal when setting the output power to be minimum, sets an outphasing angle of the first signal and the second signal when setting the output power to be maximum to be larger than an outphasing angle of the first signal and the second signal when setting the output power to be minimum, and outputs the first signal and the second signal.

An outphasing amplifier according to an aspect of the present disclosure includes: a first amplifier that amplifies a first signal; a second amplifier that amplifies a second signal; and a combiner that combines the first signal amplified by the first amplifier and the second signal amplified by the second amplifier and outputs a combined signal as an output signal, wherein an amplitude of the second signal is equal to or greater than an amplitude of the first signal when an output power of the output signal is maximum, the amplitude of the second signal is smaller than the amplitude of the first signal when the output power is minimum, and an outphasing angle of the first signal and the second signal when the output power is maximum is larger than an outphasing angle of the first signal and the second signal when the output power is minimum.

### BRIEF DESCRIPTION OF DRAWINGS

FIG. 1 is a block diagram of an outphasing amplifier according to a first embodiment.

FIG. 2 is a block diagram of the outphasing amplifier according to the first embodiment.

FIG. 3 is a block diagram of an outphasing amplifier according to a first comparative example.

FIG. 4 is a Smith chart of an impedance in the first comparative example.

FIG. 5 is a Smith chart of an impedance in the first embodiment.

FIG. 6 is a graph illustrating an outphasing angle θ with respect to an output power Po in a second comparative example.

FIG. 7 is a graph illustrating amplitudes Aa and Ab with respect to an output power Po in the second comparative example.

FIG. 8A is a schematic diagram of a vector of an output power in the second comparative example.

FIG. 8B is a schematic diagram of a vector of an output power in the second comparative example.

FIG. 9 is a graph illustrating an outphasing angle θ of an input signal with respect to an output power Po in the first embodiment.

FIG. 10 is a gaph illustrating amplitudes Aa and Ab with respect to an output power Po in Example 1.

FIG. 11A is a schematic diagram of a vector of an output power in the first embodiment.

FIG. 11B is a schematic diagram of a vector of an output power in the first embodiment.

FIG. 11C is a schematic diagram of a vector of an output power in the first embodiment.

FIG. 12 is a graph illustrating an outphasing angle θ with respect to an output power Po in a first modification of the first embodiment.

FIG. 13 is a graph illustrating amplitudes Aa and Ab with respect to an output power Po in a second modification of the first embodiment.

FIG. 14 is a graph illustrating amplitudes Aa and Ab with respect to an output power Po in a third modification of the first embodiment.

FIG. 15 is a block diagram of an outphasing amplifier according to a second embodiment.

FIG. 16 is a graph illustrating drain efficiencies with respect to an output voltage in the first embodiment and the second comparative example.

### DESCRIPTION OF EMBODIMENTS

### Technical to be Solved by Present Disclosure

By using the Chireix combiner, the impedance of the combiner viewed from the amplifiers can be set so as to improve the characteristics. However, when the outphasing angle of the two signals is out of a predetermined range, the high-frequency characteristics such as drain efficiencies of the two amplifiers deteriorate. Therefore, when the range of the outphasing angle of the two signals is set to be narrow, a dynamic range becomes small.

The present disclosure has been made in view of the above problems, and an object thereof is to increase the dynamic range of an outphasing amplifier.

### Effect of Present Disclosure

According to the present disclosure, the dynamic range of an outphasing amplifier can be increased.

### Description of Embodiments of Present Disclosure

First, embodiments of the present disclosure will be listed and described.

(1) An aspect of the present disclosure is an outphasing amplifier including: a first amplifier that amplifies a first signal; a second amplifier that amplifies a second signal; a combiner that combines the first signal amplified by the first amplifier and the second signal amplified by the second amplifier and outputs a combined signal as an output signal; and a signal processor that sets an amplitude of the second signal to be equal to or greater than an amplitude of the first signal when setting an output power of the output signal to be maximum, sets the amplitude of the second signal to be smaller than the amplitude of the first signal when setting the output power to be minimum, sets an outphasing angle of the first signal and the second signal when setting the output power to be maximum to be larger than an outphasing angle of the first signal and the second signal when setting the output power to be minimum, and outputs the first signal and the second signal. This makes it possible to increase a dynamic range.
(2) In the above (1), a saturation power of the first amplifier can be smaller than a saturation power of the second amplifier.
(3) In the above (2), the signal processor can set the amplitude of the second signal to be larger than the amplitude of the first signal when setting the output power to be maximum.
(4) In any of the above (1) to (3), the signal processor can set the amplitude of the second signal to be larger than the amplitude of the first signal when setting the output power within a first range, and can set the amplitude of the second signal so that the amplitude of the second signal decreases as the output power decreases when setting the output power within a second range smaller than the first range.
(5) In any of the above (1) to (4), the signal processor can set the amplitude of the first signal to a constant value regardless of the output power.
(6) In the above (5), the signal processor can set the amplitude of the second signal to the constant value regardless of the output power when setting the output power within a first range, and can set the amplitude of the second signal so that the amplitude of the second signal decreases as the output power decreases when setting the output power within a second range smaller than the first range.
(7) In any of the above (1) to (6), the signal processor can set the outphasing angle so that the outphasing angle decreases as the output power decreases.
(8) In any of the above (1) to (7), the combiner can be a Chireix combiner.
(9) In any one of the above (1) to (8), the outphasing angle when the output power can be set to be maximum is smaller than 90 °, and the outphasing angle when the output power can be set to be minimum is larger than 0°.
(10) An aspect of the present disclosure is an outphasing amplifier including: a first amplifier that amplifies a first signal; a second amplifier that amplifies a second signal; and a combiner that combines the first signal amplified by the first amplifier and the second signal amplified by the second amplifier and outputs a combined signal as an output signal, wherein an amplitude of the second signal is equal to or greater than an amplitude of the first signal when an output power of the output signal is maximum, the amplitude of the second signal is smaller than the amplitude of the first signal when the output power is minimum, and an outphasing angle of the first signal and the second signal when the output power is maximum is larger than an outphasing angle of the first signal and the second signal when the output power is minimum. This makes it possible to increase a dynamic range.

### Details of Embodiments of Present Disclosure

Specific examples of an outphasing amplifier according to an embodiment of the present disclosure will be described below with reference to the drawings. It should be noted that the present disclosure is not limited to these examples, and is defined by claims, and is intended to embrace all the variations within the meaning and range of equivalency of the claims.

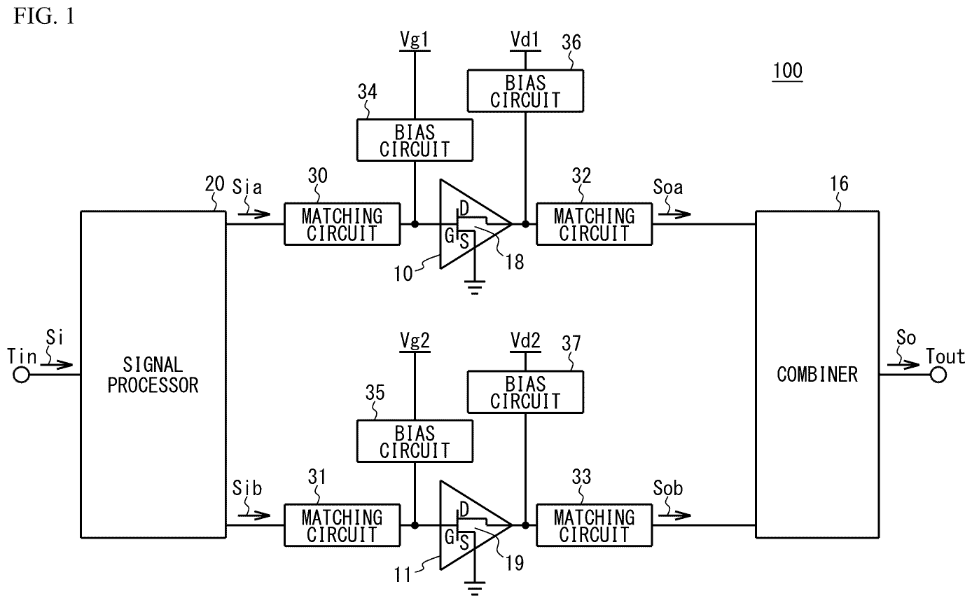

FIG. 1 is a block diagram of an outphasing amplifier according to a first embodiment. As illustrated in FIG. 1, in an outphasing amplifier 100, an amplifier 10 (first amplifier) and an amplifier 11 (second amplifier) are connected in parallel between an input terminal Tin and an output terminal Tout. A high-frequency signal is input to the input terminal Tin as an input signal Si. When the outphasing amplifier 100 is used in a base station of mobile communication, the frequency of the high-frequency signal is, for example, 0.5 GHz or more and 10 GHz or less. A signal processor 20 performs signal processing on the input signal Si and outputs the signal as two signals Sia (first signal) and Sib (second signal).

The signal Sia is input to the amplifier 10 via a matching circuit 30. The matching circuit 30 matches an output impedance of the signal processor 20 with an input impedance of the amplifier 10. The amplifier 10 amplifies the signal Sia input via the matching circuit 30, and outputs the amplified signal Soa via a matching circuit 32. The signal Soa that has passed through the matching circuit 32 is input to a combiner 16. The matching circuit 32 matches an output impedance of the amplifier 10 with an input impedance of the combiner 16. The signal Sib is input to the amplifier 11 through a matching circuit 31. The matching circuit 31 matches the output impedance of the signal processor 20 with the input impedance of the amplifier 11. The amplifier 11 amplifies the signal Sib input via the matching circuit 31, and outputs the amplified signal Sob via a matching circuit 33. The signal Sob that has passed through the matching circuit 33 is input to the combiner 16. The matching circuit 33 matches the output impedance of the amplifier 11 with the input impedance of the combiner 16. The combiner 16 combines the signals Soa and Sob. A combined signal is output from the output terminal Tout as an output signal So.

A bias circuit 34 supplies a bias voltage Vg1 to the gate G of the amplifier 10 and suppresses the leakage of the signal Sia to a bias terminal. A bias circuit 36 supplies a bias voltage Vd1 to the drain D of the amplifier 10 and suppresses leakage of the signal Soa amplified by the amplifier 10 to the bias terminal. A bias circuit 35 supplies a bias voltage Vg2 to the gate G of the amplifier 11 and suppresses the leakage of the signal Sib to the bias terminal. The bias circuit 37 supplies the bias voltage Vd2 to the drain D of the amplifier 11 and suppresses leakage of the signal Sob amplified by the amplifier 11 to the bias terminal.

The amplifiers 10 and 11 include, for example, FETs (Field Effect Transistors) 18 and 19, respectively. The sources S of the FETs 18 and 19 are grounded, the signals Sia and Sib are input to the gates G through the matching circuits 30 and 31, respectively, and the amplified signals are output from the drains D. The FETs 18 and 19 are, for example, GaN HEMT (Gallium Nitride High Electron Mobility Transistor) or LDMOS (Laterally Diffused Metal Oxide Semiconductor). Each of the amplifiers 10 and 11 may be provided with multistage FETs. The size (e.g., gate width) of the FET 18 in the amplifier 10 is smaller than the size (e.g., gate width) of the FET 19 in the amplifier 11. The matching circuits 30, 31, 32 and 33 are designed so that, for example, when the amplifiers 10 and 11 output saturation powers, the high-frequency characteristics such as the drain efficiency are optimized. This improves the high-frequency characteristics such as the drain efficiency when the amplifiers 10 and 11 amplify the signals Sia and Sib.

The signal processor 20 is, for example, a Signal Processing Unit, which digitally processes the input signal Si and outputs signals Sia and Sib. The outphasing amplifier 100 outputs the output signal So having an amplitude of the output power corresponding to the amplitude of the input power of the input signal Si. The signal processor 20 sets the outphasing angle of the signals Sia and Sib depending on the amplitude of the input signal Si in order to output the output signal So depending on the amplitude of the input signal Si.

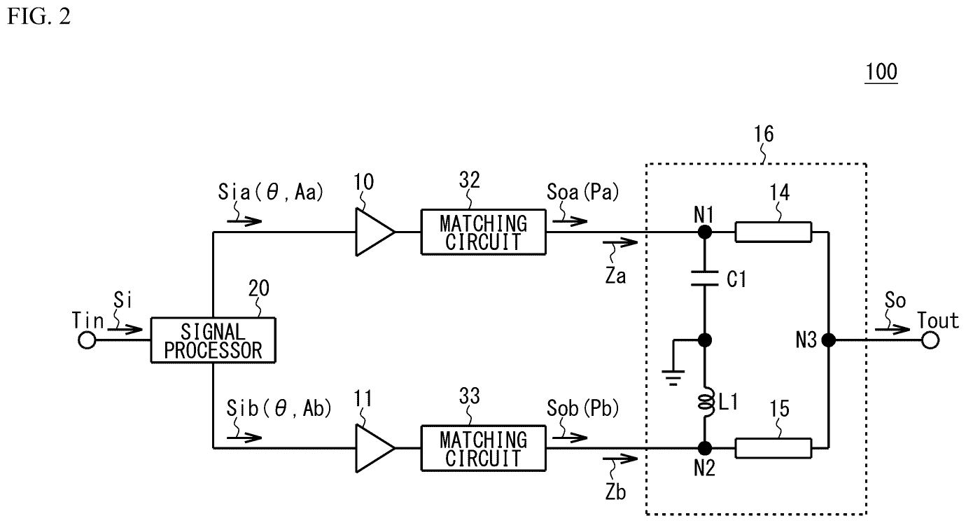

FIG. 2 is a block diagram of an outphasing amplifier according to the first embodiment. In FIG. 2, the illustration of the matching circuits 30 and 31 and the bias circuits 34, 35, 36 and 37 are omitted, and the configuration in the combiner 16 is illustrated, in comparison with FIG. 1. As illustrated in FIG. 2, in the outphasing amplifier 100 of the first embodiment, the combiner 16 is, for example, a Chireix combiner. The combiner 16 includes an inductor L1, a capacitor C1, and impedance converters 14 and 15. The capacitor C1 is shunt-connected to a node N1 through which the signal Soa passes. The inductor L1 is shunt-connected to a node N2 through which the signal Sob passes.

The impedance converters 14 and 15 have first ends connected to nodes N1 and N2, respectively, and second ends commonly connected to a node N3. The signal Soa and the signal Sob are combined at the node N3. The impedance converters 14 and 15 convert the output impedances of the matching circuits 32 and 33, respectively, to twice (100 Ω) a standard impedance (e.g. 50 Ω). As a result, an impedance viewed from the output terminal Tout toward the node N3 becomes the standard impedance (50 Ω). The impedance converters 14 and 15 are transmission lines having an electrical length of λ/4, for example. The “λ” is a wavelength at the center frequency of the operating frequency band of the outphasing amplifier 100. The electrical lengths of the impedance converters 14 and 15 are, for example, 3λ/16 or more and 5λ/16 or less.

The outphasing angle of the signals Sia and Sib output from the signal processor 20 is denoted by θ, and the amplitudes of the power of the signals Sia and Sib are denoted by Aa and Ab, respectively. When a phase difference between the signal Sia and the signal Sib is 180°, the outphasing angle θ is 0°, and when the phase difference between the signal Sia and the signal Sib is 0°, the outphasing angle θ is 90°. When the amplifiers 10 and 11 amplify the signals Sia and Sib, respectively, and output the signals Soa and Sob, the phase difference between the signals Sia and Sib and a phase difference between the amplified signals Soa and Sob are the same as each other. Therefore, the outphasing angle is also θ in the signals Soa and Sob. The powers of the signals Soa and Sob input from the matching circuits 32 and 33 to the combiner 16 are denoted by Pa and Pb, respectively. The impedances viewed from the matching circuits 32 and 33 toward the nodes N1 and N2 are denoted by Za and Zb, respectively.

### First Comparative Example

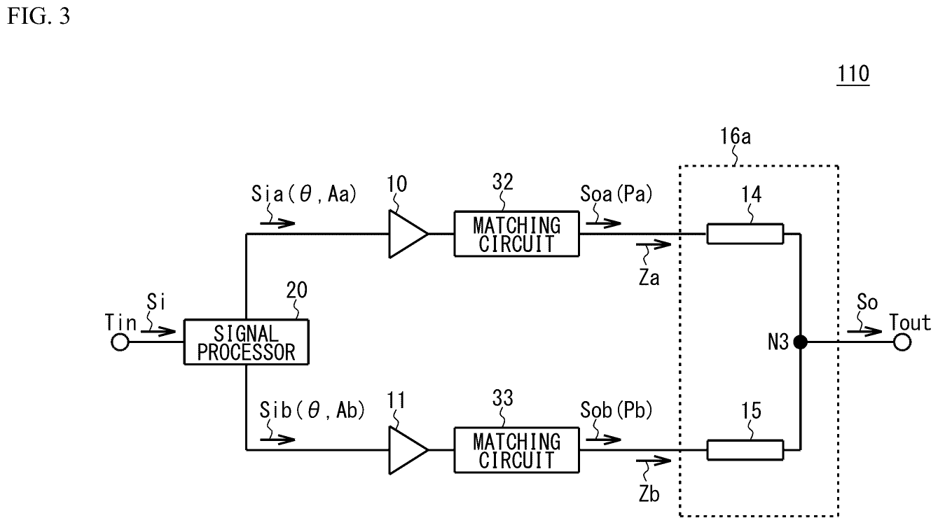

FIG. 3 is a block diagram of an outphasing amplifier according to a first comparative example. As illustrated in FIG. 3, in an outphasing amplifier 110 of the first comparative example, the inductor L1 and the capacitor C1 are not provided in a combiner 16a. Thus, the combiner 16a is not the Chireix combiner. The other configuration is the same as that of FIG. 2 of the first embodiment.

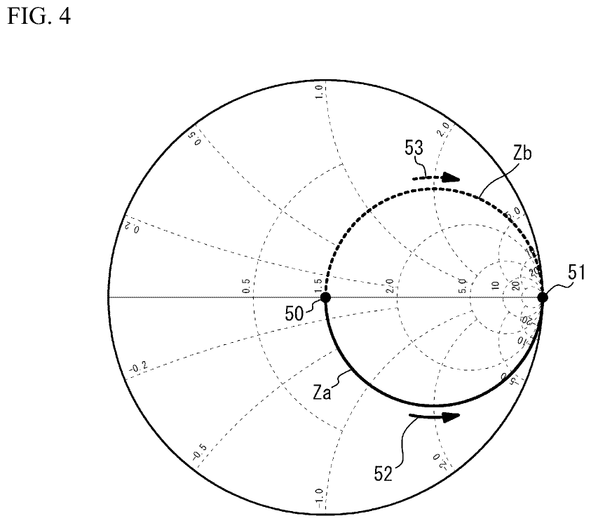

FIG. 4 is a Smith chart of impedances in the first comparative example, and is a Smith chart of the impedances Za and Zb viewed from the matching circuits 32 and 33 toward the combiner 16a. As illustrated in FIG. 4, a point 50 indicates that the outphasing angle θ is 0°, and a point 51 indicates that the outphasing angle θ is 90°. When the outphasing angle θ changes from 0° to 90°, the impedance Za moves along the locus of the lower half of an arc from the point 50 to the point 51 as indicated by an arrow 52. The impedance Zb moves along the locus of the upper half of an arc from the point 50 to the point 51 as indicated by an arrow 53.

The matching circuits 32 and 33 convert the output impedances of the amplifiers 10 and 11 so that the high-frequency characteristics of the amplifiers 10 and 11 are optimized (e.g., drain efficiency is maximum) when the impedances Za and Zb are real numbers (e.g., twice the standard impedance). As a result, in FIG. 4, when the impedances Za and Zb are real numbers, the characteristics of the amplifiers 10 and 11 are maximized. At the points 50 and 51, the impedances Za and Zb are real numbers. The range of the outphasing angle θ to be actually used is, for example, 20° or more and 70° or less. In this range, the reactance components (imaginary components) of the impedances Za and Zb are large, and the load impedances of the amplifiers 10 and 11 deviate from optimum values.

If the combiner 16a that is not the Chireix combiner is used as in the first comparative example, the load impedances of the amplifiers 10 and 11 are out of the optimum values in the range of the outphasing angle to be actually used, and thus the characteristics such as the efficiencies are deteriorated.

### Chireix Combiner

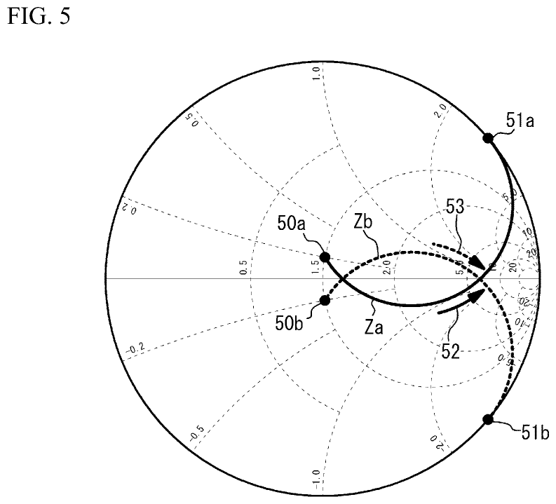

FIG. 5 is a Smith chart of the impedance in the first embodiment, and is a Smith chart of the impedances Za and Zb viewed from the matching circuits 32 and 33 toward the combiner 16. As illustrated in FIG. 5, by providing the capacitor C1, the impedance Za shifts the reactance component in a positive direction and rotates in a counterclockwise direction in a state where the shape of the entire arc is maintained on the Smith chart of the impedance, as compared with FIG. 4 of the first comparative example. By providing the inductor L1, the impedance Zb shifts the reactance component in a negative direction and rotates in a clockwise direction in a state where the shape of the entire arc is maintained on the Smith chart of the impedance, as compared with the first comparative example.

The reactance components of the impedance Za at a point 50a when the outphasing angle θ is 0° and at a point 51a when the outphasing angle θ is 90° are positive. In the range of the outphasing angle θ (for example, 20° to 70°) to be actually used, the impedance Za approaches a real axis, and the reactance component becomes small. Therefore, the load impedance of the amplifier 10 is close to the optimum value. The reactance components of the impedance Zb at a point 50b when the outphasing angle θ is 0° and at a point 51b when the outphasing angle θ is 90° are negative. In the range of the outphasing angle θ (for example, 20° to 70°) to be actually used, the impedance Zb approaches the real axis, and the reactance component becomes small. Therefore, the load impedance of the amplifier 11 is close to the optimum value. This improves the high-frequency characteristics such as the drain efficiency.

### Operation of Second Comparative Example

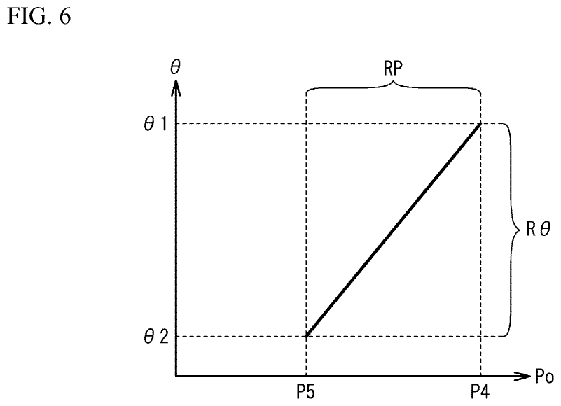

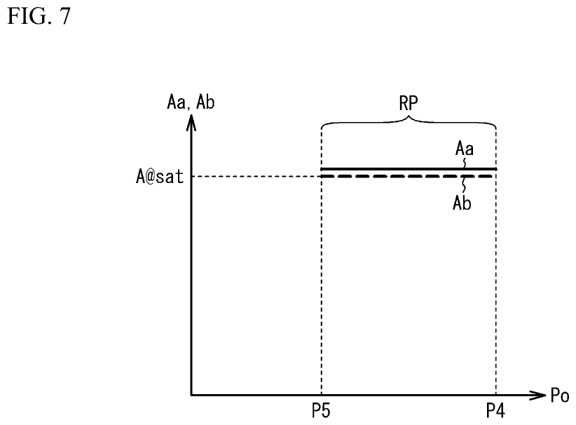

The operation of the outphasing amplifier in a second comparative example will be described. In the second comparative example, the amplifiers 10 and 11 (for example, the gate widths of the FETs) have substantially the same size. As a result, the saturation powers of the amplifiers 10 and 11 are substantially the same as each other. FIG. 6 is a graph illustrating an outphasing angle θ with respect to an output power Po in the second comparative example. In FIG. 6, a horizontal axis represents the output power Po, and a vertical axis represents the outphasing angle θ. FIG. 7 is a graph illustrating amplitudes Aa and Ab with respect to an output power Po in the second comparative example. In FIG. 7, a horizontal axis represents the output power Po of the signal So output from the output terminal Tout, and a vertical axis represents the amplitude Aa of the signal Sia and the amplitude Ab of the signal Sib output from the signal processor 20.

As illustrated in FIG. 6, in the second comparative example, a range Rθ in which the outphasing angle θ is changed is a range between a maximum angle θ1 and a minimum angle θ2. The range Rθ is determined in a range in which the reactance components of the impedances Za and Zb do not become large in FIG. 6. In the range of the range Rθ, the load impedances of the amplifiers 10 and 11 are close to the optimum values, so that the high-frequency characteristics such as the drain efficiency can be suppressed from being deteriorated. The range RP in which the output power Po is changed is a range between a maximum power P4 and a minimum power P5. The range RP is determined by the range Rθ of the outphasing angle θ. That is, the maximum power P4 is the output power Po when the outphasing angle 0 is the maximum angle θ1. The minimum power P5 is the output power Po when the outphasing angle θ is the minimum angle θ2. The signal processor 20 sets the outphasing angle θ to the maximum angle θ1 when the output power Po is the maximum power P4, and sets the outphasing angle 0 to the minimum angle θ2 smaller than the angle θ1 when the output power Po is the minimum power P5. The signal processor 20 sets the outphasing angle θ so as to gradually decrease it as the output power Po shift from the power P4 to the power P5.

As illustrated in FIG. 7, in the range RP between the maximum power P4 and the minimum power P5, the signal processor 20 sets the amplitude Aa of the signal Sia and the amplitude Ab of the signal Sib to an amplitude A@sat. The amplitude A@sat is the amplitude of the signal Sia and the signal Sib at which the output powers Pa and Pb of the amplifiers 10 and 11 become the saturation powers. Since the saturation powers of the amplifiers 10 and 11 are substantially the same as each other, the amplitudes Aa and Ab are substantially the same as each other.

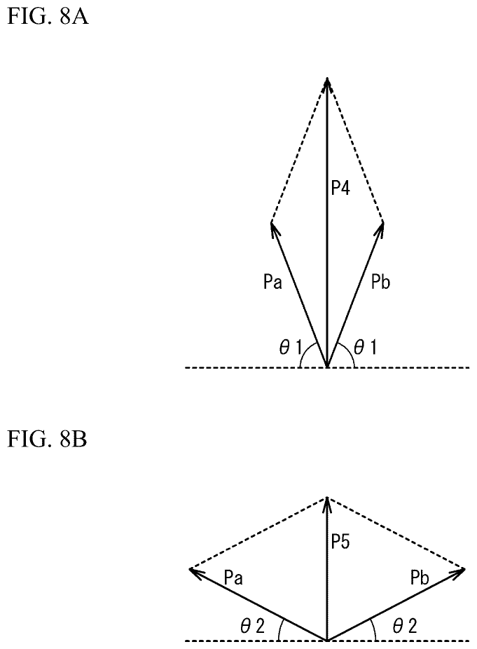

FIGS. 8A and 8B are schematic diagrams of vectors of the output power in the second comparative example. First, the outphasing angle will be described. When the phase of the signal Soa is rotated by+θ and the phase of the signal Sob is rotated by −θ from the states of the signal Soa and the signal Sob whose phases are different by 180°, the angle θ is called an outphasing angle. When the outphasing angle θ is 0°, the phase difference between the signal Soa and the signal Sob is 180°, and when the outphasing angle θ is 90°, the phase difference between the signal Soa and the signal Sob is 0°.

As illustrated in FIG. 8A, when the output power Po is the maximum power P4, the power P4 is a composite vector of a power Pa and a power Pb. The amplitude Aa of the signal Sia and the amplitude Ab of the signal Sib are the amplitudes A@sat. Therefore, the power Pa and the power Pb become saturation powers P@sat of the amplifiers 10 and 11. As illustrated in FIG. 8B, when the output power Po is the minimum power P5, the outphasing angle 0 is an angle θ2 smaller than the angle θ1. The power P5 is a composite vector of the power Pa and the power Pb. Since the angle θ2 in FIG. 8B is smaller than the angle 01 in FIG. 8A, the power P5 is smaller than the power P4. The amplifiers 10 and 11 are matched so that characteristics such as the drain efficiency are improved at the saturation power P@sat. This makes it possible to change the output power Po from the maximum power P4 to the minimum power P5 while maintaining the characteristics such as the drain efficiency.

For example, the maximum power P4 is 48 dBm and the minimum power P5 is 38 dBm. Thus, the minimum power P5 is 10 dBm lower than the maximum power P4, and a dynamic range is 10 dBm. The dynamic range is a fluctuation width of the output power Po. For example, in an amplifier for the base station, it is required to further increase the dynamic range depending on the modulation scheme. In the second comparative example, when the dynamic range is intended to be increased, the range Rθ of the outphasing angle θ is widened. However, when the range Rθ is widened, in FIG. 6, a portion where the reactance components of the impedances Za and Zb increase occurs in either part within the range Rθ.

For example, when the capacitance of the capacitor C1 and the inductance of the inductor L1 are reduced, in FIG. 5, the rotation of the impedance Za in the counterclockwise direction from FIG. 4 is reduced, and the rotation of the impedance Zb in the clockwise direction from FIG. 4 is reduced. Therefore, the reactance components of the impedances Za and Zb increase in a central portion of the range Rθ, and the load impedances of the amplifiers 10 and 11 are out of the optimum values. For example, when the capacitance of the capacitor C1 and the inductance of the inductor L1 increase, in FIG. 5, the rotation of the impedance Za in the counterclockwise direction from FIG. 4 increases, and the rotation of the impedance Zb in the clockwise direction from FIG. 4 increases. Therefore, the reactance components of the impedances Za and Zb increase at the ends of the range Rθ, and the load impedances of the amplifiers 10 and 11 are out of the optimum values. As described above, in the second comparative example, when an attempt is made to increase the dynamic range, the high-frequency characteristics such as the drain efficiency deteriorate in either part of the range RP of the output power Po.

### Operation of First Embodiment

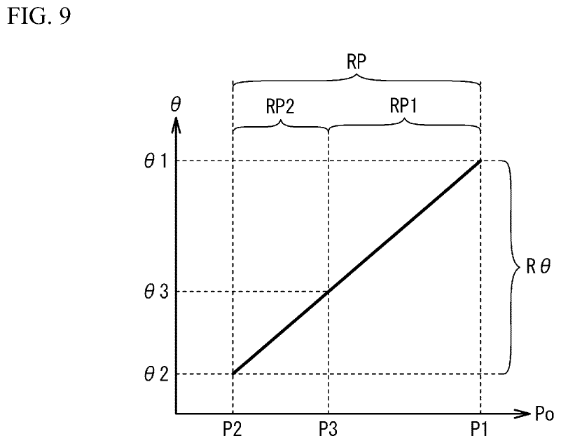

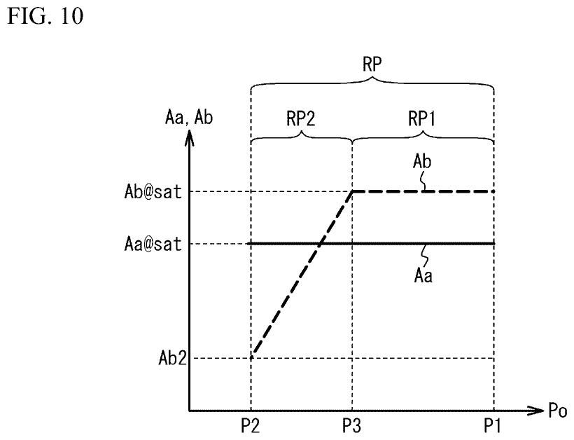

The operation of the outphasing amplifier in the first embodiment will be described. In the first embodiment, the amplifier 10 is smaller than the amplifier 11. For example, the gate width of the FET 18 is smaller than the gate width of the FET 19. As a result, the saturation power of the amplifier 10 is smaller than the saturation power of the amplifier 11. FIG. 9 is a graph illustrating an outphasing angle θ of the input signal with respect to an output power Po in the first embodiment. In FIG. 9, a horizontal axis represents the output power Po, and a vertical axis represents the outphasing angle θ. FIG. 10 is a diagram illustrating amplitudes Aa and Ab with respect to an output power Po in the first embodiment. In FIG. 10, a horizontal axis represents the output power Po of the signal So output from the outphasing amplifier 100, and a vertical axis represents the amplitude Aa of the signal Sia and the amplitude Ab of the signal Sib output from the signal processor 20.

As illustrated in FIG. 9, the range RO of the outphasing angle θ is the same as the range Rθ of FIG. 6 in the second comparative example. The maximum angle θ1 and the minimum angle θ2 of the outphasing angle θ are the same as the maximum angle θ1 and the minimum angle θ2 of the second comparative example. This makes it possible to suppress a reduction in high-frequency characteristics such as the drain efficiency because the load impedances of the amplifiers 10 and 11 are close to the optimum values. The range RP of the output power Po is wider than the range RP of FIG. 7 in the second comparative example. The maximum power of the output power Po is P1, and the minimum power is P2.

The maximum power P1 and the minimum power P2 of the first embodiment are not necessarily the same as the maximum power P4 and the minimum power P5 in the second comparative example illustrated in FIG. 6. For example, the maximum power P1 is substantially equal to the maximum power P4 in the second comparative example, but the minimum power P2 is smaller than the minimum power P5 in the second comparative example. The signal processor 20 sets the outphasing angle θ to the maximum angle 01 when the output power Po is the maximum power P1, and sets the outphasing angle θ to the minimum angle θ2 smaller than the maximum angle θ1 when the output power Po is the minimum power P2. The signal processor 20 sets the outphasing angle θ so as to gradually decrease it as the output power Po shifts from the maximum power P1 to the minimum power P2. When the output power Po is an intermediate power P3, the outphasing angle θ is an intermediate angle θ3. In FIG. 9, the outphasing angle θ changes linearly with respect to the output power Po, but may change curvilinearly.

As illustrated in FIG. 10, in the first embodiment, the range RP is divided into a range RP1 and a range RP2. The range RP1 is a range in which the output power Po is between the maximum power P1 and the intermediate power P3, and the range RP2 is a range in which the output power Po is between the intermediate power P3 and the minimum power P2. In the range RP1, the signal processor 20 sets the amplitude Aa of the signal Sia to an amplitude Aa@sat, and sets the amplitude Ab of the signal Sib to an amplitude Ab@sat. The amplitude Aa@sat is the amplitude Aa at which the output power Pa of the amplifier 10 becomes the saturation power, and the amplitude Ab@sat is the amplitude Ab at which the output power Pb of the amplifier 11 becomes the saturation power.

Since the saturation power of the amplifier 10 is smaller than the saturation power of the amplifier 11, the amplitude Aa@sat is smaller than the amplitude Ab@sat. In the range RP2, the signal processor 20 sets the amplitude Aa of the signal Sia to the amplitude Aa@sat. The signal processor 20 gradually decreases the amplitude Ab of the signal Sib from the amplitude Ab@sat to the amplitude Ab2 when reducing the output power Po from the intermediate power P3 to the minimum power P2. When the output power Po is the minimum power P2, the amplitude Ab is smaller than the amplitude Aa. In FIG. 10, the amplitude Ab changes linearly with respect to the output power Po in the range RP2, but may change curvilinearly.

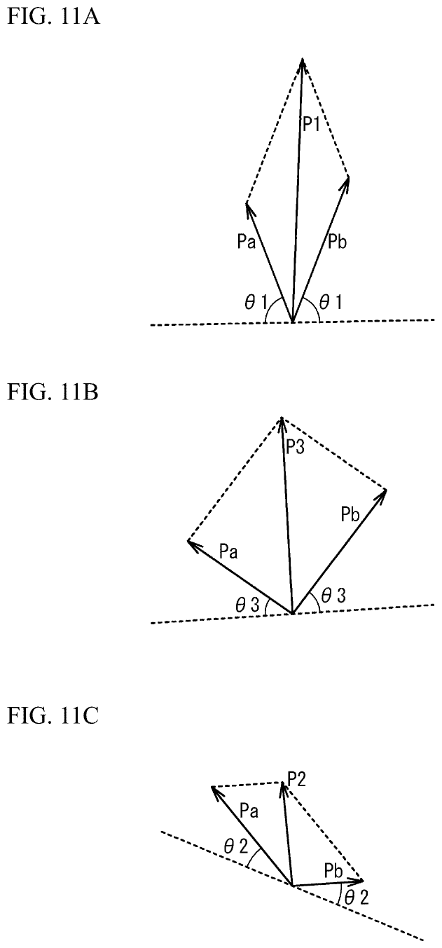

FIGS. 11A to 11C are schematic diagrams of vectors of the output power in the first embodiment. As illustrated in FIG. 11A, when the output power Po is the maximum power P1, the outphasing angle θ is the maximum angle θ1. The maximum power P1 is a composite vector of the power Pa and the power Pb. The power Pa is the saturation power Pa@sat of the amplifier 10, and the power Pb is the saturation power Pb@sat of the amplifier 11. As illustrated in FIG. 11B, when the output power Po is the intermediate power P3, the outphasing angle θ is the intermediate angle θ3 smaller than the maximum angle θ1. The intermediate power P3 is a composite vector of the power Pa and the power Pb. The power Pa is the saturation power Pa@sat of the amplifier 10, and the power Pb is the saturation power Pb@sat of the amplifier 11. Since the angle θ3 in FIG. 11B is smaller than the angle θ1 in FIG. 11A, the intermediate power P3 is smaller than the maximum power P1. In the range RP1 of the output power Po, the power Pa and the power Pb are the saturation power Pa@sat and the saturation power Pb@sat, respectively. Therefore, the amplifiers 10 and 11 can operate under matching conditions in which the high-frequency characteristics such as drain efficiency are maximized. In addition, in the range Rθ of the outphasing angle θ, the reactance components of the impedances Za and Zb are small, so that the high-frequency characteristics such as the drain efficiency can be improved.

As illustrated in FIG. 11C, when the output power Po is the minimum power P2, the outphasing angle θ is the minimum angle θ2 smaller than the intermediate angle θ3. The minimum power P2 is a composite vector of the power Pa and the power Pb. The power Pa is the saturation power Pa@sat, and the power Pb is the power Pb2 smaller than the saturation power Pb@sat. In addition to the minimum angle 02 being smaller than the intermediate angle θ3, the power Pb in FIG. 11C is smaller than the power Pb in FIG. 11B. Therefore, the minimum power P2 is smaller than the intermediate power P3. In FIG. 11C, the output power Po is mainly the power Pa amplified by the amplifier 10. Since the power Pa is the saturation power Pa@sat, the amplifier 10 can operate under the matching condition in which the high-frequency characteristics such as the drain efficiency are maximized. In the amplifier 11, the power Pb is smaller than the saturation power Pb@sat. Therefore, the high-frequency characteristics such as the drain efficiency are deteriorated in the amplifier 11. However, since the power Pb output from the amplifier 11 is smaller than the power Pa output from the amplifier 10, the deterioration of the high-frequency characteristics such as the drain efficiency can be suppressed in the entire outphasing amplifier 100.

### Operation of First Modification of First Embodiment

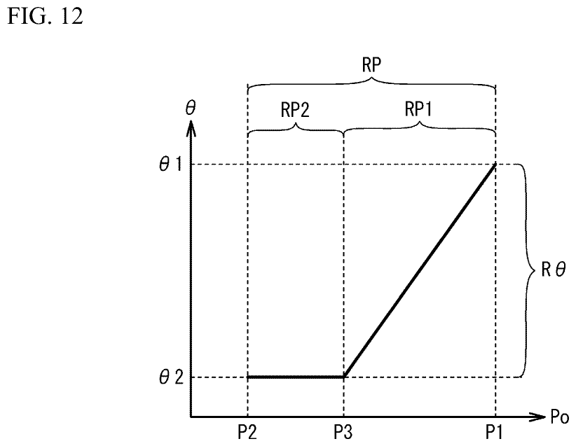

FIG. 12 is a graph illustrating an outphasing angle θ with respect to an output power Po in a first modification of the first embodiment. A relationship between the amplitude Aa and the amplitude Ab with respect to the output power Po is the same as that in FIG. 10 of the first embodiment. As illustrated in FIG. 12, the signal processor 20 sets the outphasing angle θ to the maximum angle θ1 and the minimum angle θ2 when the output power Po is the maximum power P1 and the intermediate power P3, respectively. In the range RP1 of the output power Po, the signal processor 20 sets the outphasing angle θ so that the outphasing angle θ decreases as the output power Po decreases. As illustrated in FIG. 10, in the range RP1, the signal processor 20 sets the amplitude Aa and the amplitude Ab to the amplitude Aa@sat and the amplitude Ab@sat, respectively. This allows the output power Po to be reduced from the maximum power P1 to the intermediate power P3 in the range RP1, as in the first embodiment.

In the range RP2, the signal processor 20 sets the outphasing angle θ to the constant minimum angle θ2. As illustrated in FIG. 10, in the range RP2, the signal processor 20 decreases the amplitude Ab from the amplitude Ab@sat to the amplitude Ab2 as the output power Po shifts from the intermediate power P3 to the minimum power P2. Therefore, even if the outphasing angle θ is constant in the range RP2, the output power Po can be decreased from the intermediate power P3 to the minimum power P2. In FIG. 12, the outphasing angle θ changes linearly with respect to the output power Po in the range RP1, but may change curvilinearly.

### Operation of Second Modification of First Embodiment

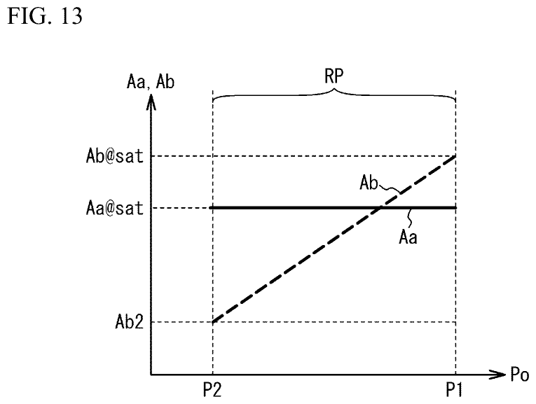

FIG. 13 is a graph illustrating amplitudes Aa and Ab with respect to an output power Po in a second modification of the first embodiment. The relationship between the output power Po and the outphasing angle θ is the same as that illustrated in FIG. 9 of the first embodiment or FIG. 12 of the first modification of the first embodiment. As illustrated in FIG. 13, the signal processor 20 may gradually decrease the amplitude Ab from the amplitude Ab@sat to the amplitude Ab2 as the output power Po shift from the maximum power P1 to the minimum power P2. In the second modification of the first embodiment, except when the output power Po is the maximum power P1, the amplitude Ab of the signal Sib is deviated from the amplitude Ab@sat. Therefore, the high-frequency characteristics such as the drain efficiency of the amplifier 11 are deteriorated as compared with the first embodiment and the first modification thereof. However, the output power Po at the time when the outphasing angle θ is the minimum angle θ2 can be set to the minimum power P2 smaller than the minimum power P5 in the second comparative example. Therefore, the dynamic range can be increased.

### Operation of Third Modification of First Embodiment

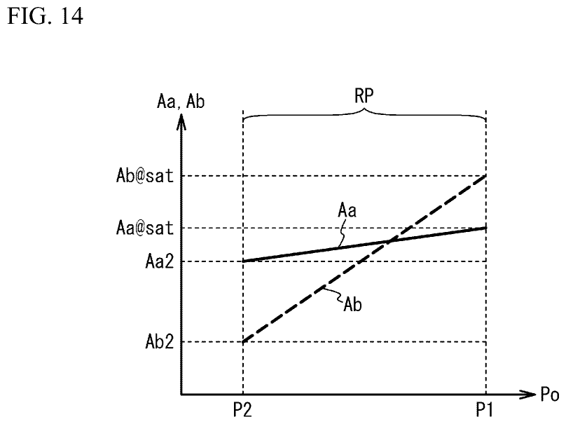

FIG. 14 is a graph illustrating amplitudes Aa and Ab with respect to an output power Po in a third modification of the first embodiment. The relationship between the output power Po and the outphasing angle θ is the same as that illustrated in FIG. 9 of the first embodiment or FIG. 12 of the first modification of the first embodiment. As illustrated in FIG. 14, the signal processor 20 may gradually decrease the amplitude Aa from the amplitude Aa@sat to the amplitude Aa2 as the output power Po shifts from the maximum power P1 to the minimum power P2. In the third modification of the first embodiment, except when the output power Po is the maximum power P1, the amplitude Aa of the signal Sia is deviated from the amplitude Aa@sat. Therefore, the high-frequency characteristics such as the drain efficiency of the amplifier 10 are deteriorated as compared with the second modification of the first embodiment. However, the output power Po at the time when the outphasing angle θ is the minimum angle θ2 can be set to the minimum power P2 smaller than the minimum power P5 in the second comparative example. Therefore, the dynamic range can be increased.

### Second Embodiment

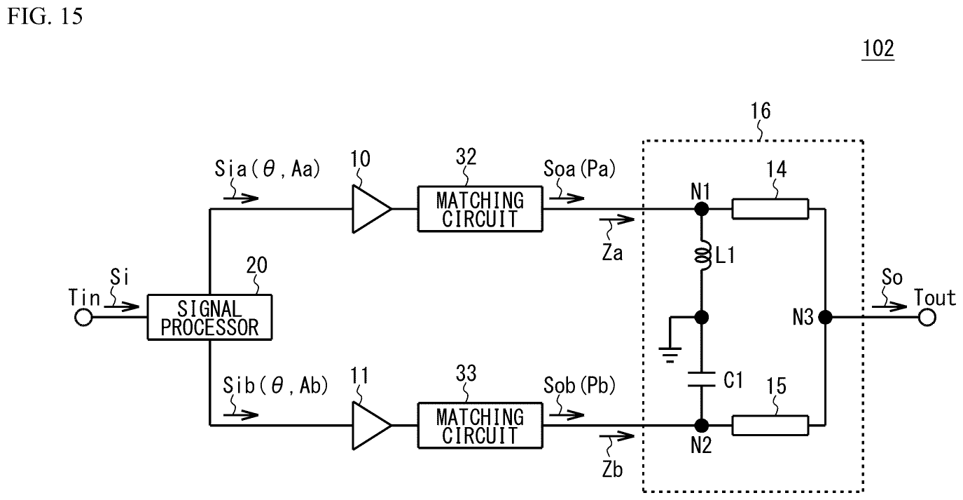

FIG. 15 is a block diagram of an outphasing amplifier according to a second embodiment. As illustrated in FIG. 15, in an outphasing amplifier 102 of the second embodiment, the inductor L1 is shunt-connected to the node N1, and the capacitor C1 is shunt-connected to the node N2 in the combiner 16. The signal processor 20 reverses the phase of the signal Sia with respect to the phase of the signal Sia in the first embodiment and the modifications thereof, and reverses the phase of the signal Sib with respect to the phase of the signal Sib in the first embodiment and the modifications thereof. This allows the outphasing amplifier of the second embodiment to operate in the same manner as the first embodiment and the modifications thereof. The other configurations are the same as those of the first embodiment and the modifications thereof, and the description thereof is omitted.

According to the first embodiment and the modifications thereof, the signal processor 20 sets the output power Po of the output signal So within the range RP between the maximum power P1 and the minimum power P2. When the output power Po is set to the maximum power P1, the amplitude Ab is set to be equal to or larger than the amplitude Aa. When the output power Po is set to the minimum power P2, the amplitude Ab is set smaller than the amplitude Aa. For example, the amplitude Ab is set smaller than the amplitude Aa by 0.1 dB or more or 0.5 dB or more. The outphasing angle θ1 when the output power Po is set to the maximum power P1 is set to be larger than the outphasing angle θ2 when the output power Po is set to the minimum power P2. For example, the angle θ1 is set to be larger than the angle θ2 by 10° or more or 20° or more. As a result, the minimum power P2 can be made smaller than the minimum power P5 in the second comparative example at the outphasing angle θ of the angle θ2 where the reactance components of the impedances Za and Zb are small and the load impedances of the amplifiers 10 and 11 do not deviate significantly from the optimum values. Therefore, the dynamic range can be increased without deteriorating the high-frequency characteristics such as the drain efficiency.

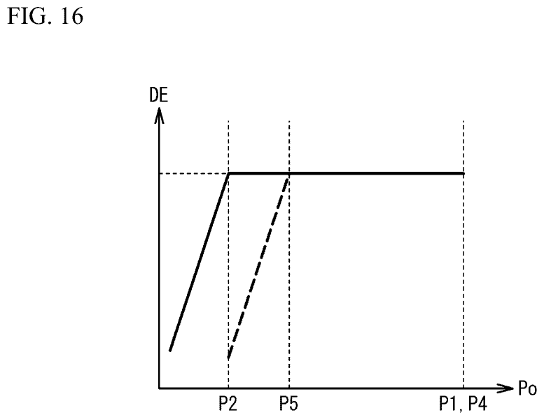

A drain efficiency DE will be described as an example. FIG. 16 is a graph illustrating drain efficiencies with respect to an output power in the first embodiment and the second comparative example. In FIG. 16, a horizontal axis represents the output power Po, and a vertical axis represents the drain efficiency DE. A broken line illustrates the second comparative example, and a solid line illustrates the first embodiment. As illustrated in FIG. 16, in the first embodiment and the second comparative example, the maximum powers P1 and P4 of the output power Po are substantially the same as each other. In the second comparative example, when the output power Po is equal to or less than the minimum power P5, the drain efficiency decreases. This is because the outphasing angle θ becomes smaller than the minimum angle θ2, the reactance components of the impedances Za and Zb become large, and the load impedances of the amplifiers 10 and 11 deviate from the optimum values. In the first embodiment, the drain efficiency DE hardly decreases until the output power Po reaches the minimum power P2 lower than the minimum power P5 in the second comparative example. This is because the output power Po can be set to the minimum power P2 smaller than the minimum power P5 in the second comparative example even when the outphasing angle θ is set to the minimum angle θ2.

The saturation power Pa@sat of the amplifier 10 and the saturation power Pb@sat of the amplifier 11 may be substantially the same as each other. Also in this case, when the outphasing angle θ is set to the minimum angle θ2, the amplitude Ab is set smaller than the amplitude Aa. This makes it possible to make the output power Po smaller than the minimum power P5 in the second comparative example. Therefore, the dynamic range can be made larger than that of the second comparative example.

As illustrated in FIG. 10, the saturation power Pa@sat of the amplifier 10 is smaller than the saturation power Pb@sat of the amplifier 11. For example, the saturation power Pa@sat is smaller than the saturation power Pb@sat by 1 dB or more. Thus, when the outphasing angle θ is set to the minimum angle θ2, the output power Po can be further decreased. Therefore, the dynamic range can be further increased.

At this time, when the output power Po is set to the maximum power P1, the amplitude Ab of the signal Sib is set to be larger than the amplitude Aa of the signal Sia. Thus, when the outphasing angle θ is set to the minimum angle θ2, the output power Po can be further decreased. Therefore, the dynamic range can be further increased.

As illustrated in FIGS. 10 and 13, the signal processor 20 sets the amplitude Aa to a constant value regardless of the output power Po. Thus, the load impedance of the amplifier 10 is set so that the high-frequency characteristics are optimized when the amplitude Aa is the constant value, whereby the high-frequency characteristics of the amplifier 10 can be improved. The expression “the amplitude Aa is constant (or substantially constant)” means that the amplitude Aa is constant within a controllable range, and for example, a variation of about ±1 dB in the amplitude Aa is allowed. The constant value of the amplitude Aa can be set as a value at which the output power Po becomes the saturation power. This makes it possible to increase the output power Po.

As illustrated in FIG. 10, when the output power Po is set within the range RP1 (first range), the signal processor 20 sets the amplitude Ab to the constant value regardless of the output power Po. When the output power Po is set within a range RP2 (second range) that is smaller than the range RP1, the signal processor 20 sets the amplitude Ab so that the amplitude Ab decreases as the output power Po decreases. Thus, the load impedance of the amplifier 11 is set so that the high-frequency characteristic is optimized when the amplitude Ab is the constant value, whereby the high-frequency characteristic of the amplifier 11 can be improved in the range RP2. The expression “the amplitude Ab is constant (or substantially constant)” means that the amplitude Ab is constant within a controllable range, and for example, a variation of about ±1 dB in the amplitude Ab is allowed. The constant value of the amplitude Ab can be set as a value at which the output power Po becomes the saturation power. This makes it possible to increase the output power Po.

When the output power Po is set within the range RP1, the signal processor 20 sets the amplitude Ab to be larger than the amplitude Aa. When the output power Po is set within the range RP2, the signal processor 20 sets the amplitude Ab so that the amplitude Ab decreases as the output power Po decreases. As a result, in the range RP1, the amplifiers 10 and 11 can be operated under conditions close to the optimum operating conditions. In the range RP2, the amplifier 11 is out of the optimum operating conditions as compared with the amplifier 10, but the output power Pb of the amplifier 11 is smaller than the output power Pa of the amplifier 10, so that the deterioration of the high-frequency characteristics can be suppressed.

As illustrated in FIGS. 9 and 12, the signal processor 20 sets the outphasing angle θ so that the outphasing angle θ decreases as the output power Po decreases. This makes it possible to control the output power Po by the outphasing angle θ. As illustrated in FIG. 9, the outphasing angle θ may gradually decrease as the output power Po decrease. As illustrated in FIG. 12, the outphasing angle θ may be constant in a part of the range RP (for example, the range RP2).

The maximum angle θ1 when the output power Po is set to the maximum power P1 is smaller than 90°, and the minimum angle θ2 when the output power Po is set to the minimum power P2 is larger than 0°. This makes it possible to decrease the reactance components of the impedances Za and Zb in the range between the maximum angle θ1 and the minimum angle θ2. The maximum angle θ1 can be 80° or less, or can be 70 ° or less. The minimum angle θ2 may be 10° or more, or may be 20° or more.

The combiner 16 is not necessarily the Chireix combiner, but is the Chireix combiner. As a result, as described with reference to FIGS. 4 and 5, the characteristics such as the drain efficiency can be improved.

The embodiments disclosed herein should be considered in all respects exemplary and not restrictive. The scope of the present disclosure is not limited to the embodiment described above, is set forth by the claims and is intended to include all variations within the meaning and scope of equivalents of the claims.

### REFERENCE SIGNS LIST

Sia, Sib signal (first signal, second signal)
Si input signal
Soa, Sob signal
So output signal
Po output power
P1, P2, P3, P4, P5 Power
Tin input terminal
Tout output terminal
θ outphasing angle
θ1, θ2, θ3 angle
Aa, Ab amplitude
10, 11 amplifier (first amplifier, second amplifier)
14, 15 impedance converter
16, 16a combiner
18, 19 FET
20 signal processor
30, 31, 32, 33 matching circuit
34, 36 bias circuit
50, 50a, 50b, 51, 51a, 51b point
52, 53 arrow
100 outphasing amplifier

1. An outphasing amplifier comprising:
a first amplifier that amplifies a first signal;
a second amplifier that amplifies a second signal;
a combiner that combines the first signal amplified by the first amplifier and the second signal amplified by the second amplifier and outputs a combined signal as an output signal; and
a signal processor that sets an amplitude of the second signal to be equal to or greater than an amplitude of the first signal when setting an output power of the output signal to be maximum in operation, sets the amplitude of the second signal to be smaller than the amplitude of the first signal when setting the output power to be minimum in operation, sets an outphasing angle of the first signal and the second signal when setting the output power to be maximum in operation to be larger than an outphasing angle of the first signal and the second signal when setting the output power to be minimum in operation, and outputs the first signal and the second signal,
wherein the outphasing angle is set so that the outphasing angle decreases as the output power decreases when setting the output power within a first range including a case where the output power is maximum in operation, and
wherein when the output power is maximum in the operation, output powers of the first amplifier and the second amplifier are saturation powers.

2. The outphasing amplifier according to claim 1, wherein
a saturation power of the first amplifier is smaller than a saturation power of the second amplifier.

3. The outphasing amplifier according to claim 2, wherein
the signal processor sets the amplitude of the second signal to be larger than the amplitude of the first signal when setting the output power to be maximum in operation.

4. The outphasing amplifier according to claim 1, wherein
the signal processor sets the amplitude of the second signal to be larger than the amplitude of the first signal when setting the output power within a first range, sets the amplitude of the second signal so that the amplitude of the second signal decreases as the output power decreases when setting the output power within a second range smaller than the first range, and sets the outphasing angle so that the outphasing angle decreases as the output power decreases or so that the outphasing angle becomes constant regardless of the output power.

5. The outphasing amplifier according to claim 1, wherein
the signal processor sets the amplitude of the first signal to a constant value regardless of the output power between the case where the output power is maximum in operation and a case where the output power is minimum in operation.

6. The outphasing amplifier according to claim 5, wherein
the signal processor sets the amplitude of the second signal to the constant value regardless of the output power when setting the output power within a first range, sets the amplitude of the second signal so that the amplitude of the second signal decreases as the output power decreases when setting the output power within a second range smaller than the first range, and sets the outphasing angle so that the outphasing angle decreases as the output power decreases or so that the outphasing angle becomes constant regardless of the output power.

7. The outphasing amplifier according to claim 1, wherein
the signal processor sets the outphasing angle so that the outphasing angle decreases as the output power decreases between the case where the output power is maximum in operation and a case where the output power is minimum in operation.

8. The outphasing amplifier according to claim 1, wherein
the combiner is a Chireix combiner.

9. The outphasing amplifier according to claim 1, wherein
the outphasing angle when the output power is set to be maximum is smaller than 90°, and the outphasing angle when the output power is set to be minimum is larger than 0°

10. An outphasing amplifier comprising:
a first amplifier that amplifies a first signal;
a second amplifier that amplifies a second signal; and
a combiner that combines the first signal amplified by the first amplifier and the second signal amplified by the second amplifier and outputs a combined signal as an output signal,
wherein an amplitude of the second signal is equal to or greater than an amplitude of the first signal when an output power of the output signal is maximum in operation, the amplitude of the second signal is smaller than the amplitude of the first signal when the output power is minimum in operation, an outphasing angle of the first signal and the second signal when the output power is maximum in operation is larger than an outphasing angle of the first signal and the second signal when the output power is minimum in operation, and the outphasing angle decreases as the output power decreases when the output power is set within a first range including a case where the output power is maximum in operation, and
wherein when the output power is maximum in the operation, output powers of the first amplifier and the second amplifier are saturation powers.
